(19) United States
(12) Patent Application Publication
(10) Pub. No.: US 2022/0298620 A1
(43) Pub. Date: Sep. 22, 2022

(54) ENHANCED OXIDATION WITH HYDROGEN RADICAL PRETREATMENT

(71) Applicant: Applied Materias, Inc., Santa Clara, CA (US)

(72) Inventors: Matthew Spuller, Belmont, CA (US); Pradeep Sampath Kumar, San Jose, CA (US); Shashank Sharma, Sunnyvale, CA (US); Norman Tam, Cupertino, CA (US)

(21) Appl. No.: 17/666,188

(22) Filed: Feb. 7, 2022

Related U.S. Application Data
(60) Provisional application No. 63/164,411, filed on Mar. 22, 2021.

(51) Int. Cl. C23C 8/10; C23C 8/02

(52) U.S. Cl. CPC C23C 8/10; C23C 8/02

(57) ABSTRACT

Enhanced oxidation with hydrogen radical pretreatment is described. In an example, a method of oxidizing a substrate includes positioning a substrate in a processing volume of a processing chamber, generating hydrogen radicals using a remote plasma source fluidly coupled to the processing chamber, exposing a surface of the substrate to the generated hydrogen radicals, and, subsequent to exposing the substrate to the generated hydrogen radicals, oxidizing the surface of the substrate to form an oxide layer on the surface of the substrate.

### CROSS-REFERENCE TO RELATED APPLICATIONS

This application claims the benefit of U.S. Provisional Application No. 63/164,411, filed on Mar. 22, 2021, the entire contents of which are hereby incorporated by reference herein.

### BACKGROUND

### 1) Field

Embodiments of the present disclosure pertain to the field of reactor or plasma processing chambers and, in particular, to enhanced oxidation with hydrogen radical pretreatment.

### 2) Description of Related Art

In microfabrication, thermal oxidation is a way to produce a thin layer of oxide (usually silicon dioxide) on the surface of a wafer. The technique forces an oxidizing agent to diffuse into the wafer at high temperature and react with it. Thermal oxidation may be applied to different materials, but most commonly involves the oxidation of silicon substrates to produce silicon dioxide.

Most thermal oxidation is performed in furnaces, at temperatures between 800 and 1200° C. A single furnace accepts many wafers at the same time. Historically, the single furnace held the wafers vertically, beside each other. However, many modern designs hold the wafers horizontally, above and below each other, and load them into the oxidation chamber from below. More recently, single wafer chambers have been used for thermal oxidation processes.

Improvements are still needed in the area of thermal oxidation processes.

### SUMMARY

Embodiments of the present disclosure include enhanced oxidation with hydrogen radical pretreatment.

In an embodiment, a method of oxidizing a substrate includes positioning a substrate in a processing volume of a processing chamber, generating hydrogen radicals using a remote plasma source fluidly coupled to the processing chamber, exposing a surface of the substrate to the generated hydrogen radicals, and, subsequent to exposing the substrate to the generated hydrogen radicals, oxidizing the surface of the substrate to form an oxide layer on the surface of the substrate.

### BRIEF DESCRIPTION OF THE DRAWINGS

FIGS. 1A and 1B are schematic sectional views of exemplary processing chambers which may be used to perform the methods set forth herein, in accordance with an embodiment of the present disclosure.

FIG. 2 is a schematic plan view of a multi-chamber processing system which may be used to perform the methods set forth herein, in accordance with an embodiment of the present disclosure.

FIG. 3 is a diagram illustrating a method involving enhanced oxidation with hydrogen radical pretreatment, in accordance with an embodiment of the present disclosure.

FIG. 4 illustrates a block diagram of an exemplary computer system, in accordance with an embodiment of the present disclosure.

### DETAILED DESCRIPTION

Enhanced oxidation with hydrogen radical pretreatment is described. In the following description, numerous specific details are set forth in order to provide a thorough understanding of embodiments of the present disclosure. It will be apparent to one skilled in the art that embodiments of the present disclosure may be practiced without these specific details. In other instances, well-known aspects are not described in detail in order to not unnecessarily obscure embodiments of the present disclosure. Furthermore, it is to be understood that the various embodiments shown in the Figures are illustrative representations and are not necessarily drawn to scale.

One or more embodiments are directed to enhanced oxidation processes including a hydrogen radical pretreatment.

To provide context, oxidation thickness is conventionally limited by conditions of an oxidation process such as temperature, pressure and flow rate of the oxidation source. In accordance with one or more embodiments of the present disclosure, by using a hydrogen radical pretreatment, an achievable oxide thickness is increased.

In an embodiment, by pretreating a substrate with a hydrogen radical process, an oxide thickness of a substrate is increased during oxidation. In one particular example, whereas only a 20 Angstroms oxide thickness may be possible at a particular temperature and oxidation process, a 30 Angstroms oxide can be realized if the oxidation process is preceded by a hydrogen radical pretreatment process.

Implementation of approaches herein for increasing oxide thickness using a hydrogen radical pretreatment can be distinguished from conventional approaches for optimization of oxidation conditions. Implementation of approaches herein can provide benefits such as lower thermal budget, and can enable lower demands on the oxidation process (such as remote plasma source power, oxidant flow rates, gas delivery components, etc.).

In accordance with one or more embodiments of the present disclosure, a hydrogen radical remote plasma source (RPS) process includes flowing a hydrogen source through a remote plasma source, generating hydrogen radicals in the plasma source, and delivering the hydrogen radicals to a substrate, thereby pretreating the substrate for enhanced oxidation. Embodiments described herein may involve one or more of hydrogen, an oxidation, a remote plasma.

In an embodiment, a radical pretreatment with hydrogen (H) for oxidation can be effected by performing a hydrogen radical exposure for a duration in the range of 1 second to 5 minutes, at a temperature in the range of 25 degrees Celsius to 700 degrees Celsius, using a gas flow of hydrogen (H₂) in a range of 1% to 100% total H₂ in the flow, with or without argon (Ar) or other gases, at a pressure in a range of 0.01 Torr to 20 Torr.

In an embodiment, a subsequent oxidation process can be performed by implementing an oxygen source exposure for a duration in the range of 1 second to 20 minutes, at a temperature in the range of 25 degrees Celsius to 1200 degrees Celsius, using a gas flow of water vapor (H₂O) or oxygen (O₂), or other oxidation source, in a range of 1% to 100% total oxidation source in the flow, with or without argon (Ar) or other gases, at a pressure in a range of 0.1 Torr to 800 Torr.

In accordance with one or more embodiments of the present disclosure, the hydrogen pretreatment is performed in the same chamber, and in the same process recipe (e.g., computer program), as the subsequent oxidation process. In other embodiments, the hydrogen pretreatment is performed using separate process recipes in a same chamber as the subsequent oxidation process. In yet other embodiments, the hydrogen pretreatment and the subsequent oxidation process are performed in two different chambers on the same integrated platform, or in separate chambers on separate platforms. In one or more embodiments, the hydrogen pretreatment is an in situ process. In other embodiments, the hydrogen pretreatment is an ex situ process. In either case, a benefit of hydrogen pretreatment for enhanced oxidation may be realized, although the benefit may be of a different magnitude among such configurations.

In an embodiment, implementation of a hydrogen radical pretreatment together with an oxidation process provides an approximately 50% increase in oxide thickness relative to a same oxidation process implemented without the use a hydrogen radical pretreatment. In a particular embodiment, implementation of a hydrogen radical pretreatment together with an oxidation process provides an approximately 30 Angstroms oxide thickness relative to an approximately 20 Angstroms oxide thickness using a same oxidation process implemented without the use a hydrogen radical pretreatment.

In an embodiment, an enhanced oxidation process as described herein is implemented in an enhanced treatment chamber. In one embodiment, the chamber is a radical-assisted thermal treatment chamber on a platform for targeting treatment applications. In one embodiment, a chamber body for enabling high exhaust conductance is used, e.g., for an approximately 0.1 Torr plasma processing condition. In one embodiment, the chamber includes one or more of a process kit, a showerhead, and/or a pumping plenum design specifically for radical distribution. In one embodiment, the chamber is targeted for H₂-based radicals.

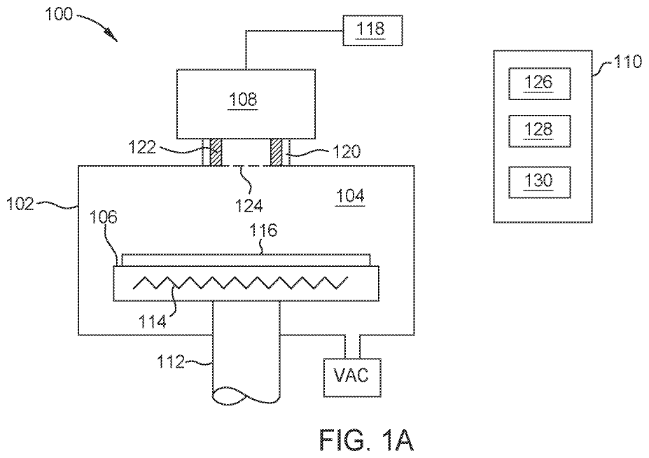

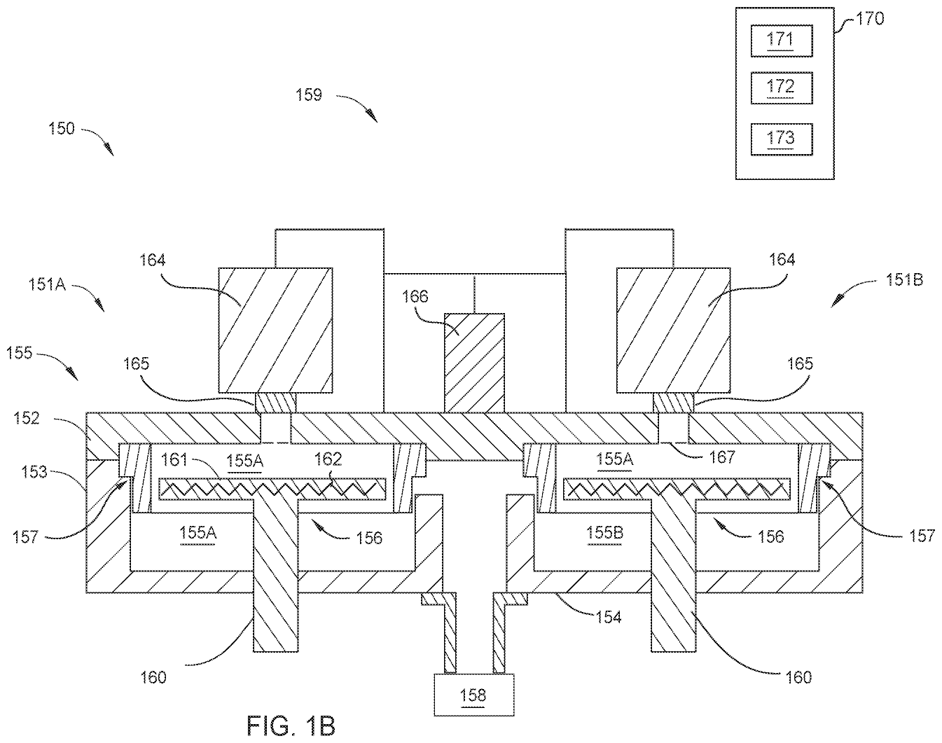

FIGS. 1A and 1B are schematic sectional views of exemplary processing chambers which may be used to perform the methods set forth herein, in accordance with an embodiment of the present disclosure.

FIG. 1A schematically illustrates an exemplary thermal processing system, processing chamber 100, which may be used to perform aspects of the methods described herein. Here, the processing chamber 100 features a chamber body 102 that defines a processing volume 104, a substrate support assembly 106 disposed in the processing volume 104, a remote plasma source (RPS) 108 fluidly coupled to the processing volume 104, and a system controller 110. The processing volume 104 is fluidly coupled to a vacuum source, such as to one or more dedicated vacuum pumps, which maintains the processing volume 104 at sub-atmospheric conditions and evacuates processing and other gases therefrom. The substrate support assembly 106 includes a substrate support 107 disposed on a support shaft 112, which sealingly extends through a base of the chamber body 102, such as being surrounded by a bellows (not shown) in a region above or below the chamber base. Herein, the substrate support 107 includes a heater 114, e.g., a resistive heating element, that is used to heat the substrate support 107, and thus a substrate 116 disposed on the substrate support 107, to a desired processing temperature.

The RPS 108 is fluidly coupled to a hydrogen gas source 118 and is used to generate hydrogen radicals which are then flowed into the processing volume 104 through a conduit 120 fluidly coupled there between. In some embodiments, the conduit 120 features a dielectric liner 122, e.g., a quartz liner or an alumina liner, disposed therein. The dielectric liner 122 beneficially reduces the recombination of the radical species that might otherwise occur between the RPS 108 and the processing volume 104.

Generally, plasma excitation of the hydrogen gas to form neutral hydrogen radicals also forms charged hydrogen ions that may be accelerated towards the substrate 116 and cause undesirable damage to the features formed in the surface thereof. Thus, in some embodiments, the processing chamber 100 further includes an ion filter 124 disposed between the RPS 108 and the substrate support 107. The ion filter 124 is used to remove hydrogen ions from the effluent of the RPS 108. Examples of suitable ion filters which may be used with the processing chamber 100 include electrostatic filters, wire or mesh filters, plates with relatively aspect ratio openings (e.g., >2:1), and magnetic ion filters. In embodiments herein, the ion filter 124 removes substantially all of the generated ion radicals from the RPS effluent before the effluent reaches the processing volume 104. As used herein “substantially all of the generated hydrogen ions” means about 95% of the hydrogen ions generated by the RPS 108 or more.

Operation of the processing chamber 100 is facilitated by the system controller 110. The system controller 110 includes a programmable central processing unit, here the CPU 126, which is operable with a memory 128 (e.g., non-volatile memory) and support circuits 130. The CPU 126 is one of any form of general purpose computer processor used in an industrial setting, such as a programmable logic controller (PLC), for controlling various chamber components and sub-processors. The memory 128, coupled to the CPU 126, is non-transitory and is in the form of a computer-readable storage media containing instructions (e.g., non-volatile memory), that when executed by the CPU 126, facilitates the operation of the processing chamber. The support circuits 130 are conventionally coupled to the CPU 126 and include cache, clock circuits, input/output subsystems, power supplies, and the like, and combinations thereof coupled to the various components the processing chamber, to facilitate control of substrate processing operations therewith.

Here, the instructions in the memory 128 are in the form of a program product such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure. In some embodiments, the processing chamber 100 may include any one or combination of the features of the processing system 150 described in FIG. 1B.

FIG. 1B is a schematic cross-sectional view illustrating a processing system 150, according to one embodiment, which may be used to perform the methods set forth herein. Here, the processing system 150 features tandem processing chambers 151A-B having a chamber lid 152, one or more chamber walls 153, and a chamber base 154 which collectively define a first chamber volume 155A and a second chamber volume 155B. Here, the configuration of each of the processing chambers 151A-B are substantially similar to one another to facilitate concurrent processing of a plurality of substrates (not shown) under the same or substantially similar process conditions. One or both of the processing chambers 151A-B may include any one or combination of the features of the processing chamber 100 described in FIG. 1A. In other embodiments, the configuration of the processing chambers 151A-B, e.g., one or more features and components thereof, are different from one another.

Each of the chamber volumes 155A-B has a respective substrate support assembly 156 disposed therein and a process kit 157 including one or more shields or liners used to shield processing components from the chamber volumes 155A-B and to direct the flow of gases therein. The chamber volumes 155A-B are fluidly coupled to a common vacuum source 158, such as one or more dedicated vacuum pumps, which are used to maintain the chamber volumes 155A-B at sub-atmospheric conditions and to evacuate processing and other gases therefrom. Processing gases are respectively delivered to the chamber volumes 155A-B using a common gas delivery system 159.

Here, each substrate support assembly 156 includes a support shaft 160 movably disposed through the chamber base 154, and a substrate support 161 disposed on the support shaft 160. Here, each of the substrate supports 161 as includes a heater 162 such as a resistive heating element, used to heat and maintain a substrate at a desired processing temperature. The chamber lid 152, the substrate supports 161, and shields and liner of the corresponding process kits 157 collectively define respective processing volumes 163A-B when the substrate supports 161 are in a raised position.

As shown, each of the processing volumes 163A-B is fluidly coupled to a respective remote plasma source (RPS) 164 using a gas conduit 165 disposed there between. Each RPS 164 is fluidly coupled to a water ampoule 166 of the gas delivery system 159 which deliver processing and other gases thereto. In some embodiments, each of the gas conduits 165 includes a dielectric liner (not shown), such as the dielectric liner 122 described in FIG. 1A, and the processing system 150 further includes one or more ion filters 167 disposed between each RPS 164 and the substrate support 161 disposed in the processing volumes 163A-B. The ion filter 167 may be the same or substantially similar to the ion filter 124 described in FIG. 1A. In other embodiments, a single remote plasma source may be used to deliver activated species to each of the processing volumes 163A-B.

Operation of the processing system is facilitate by a system controller 170 which includes a CPU 171, memory 172, and support circuits 173 which are configured as described for the system controller 110 of FIG. 1A and include instructions in the memory 172 for implementing the methods described herein.

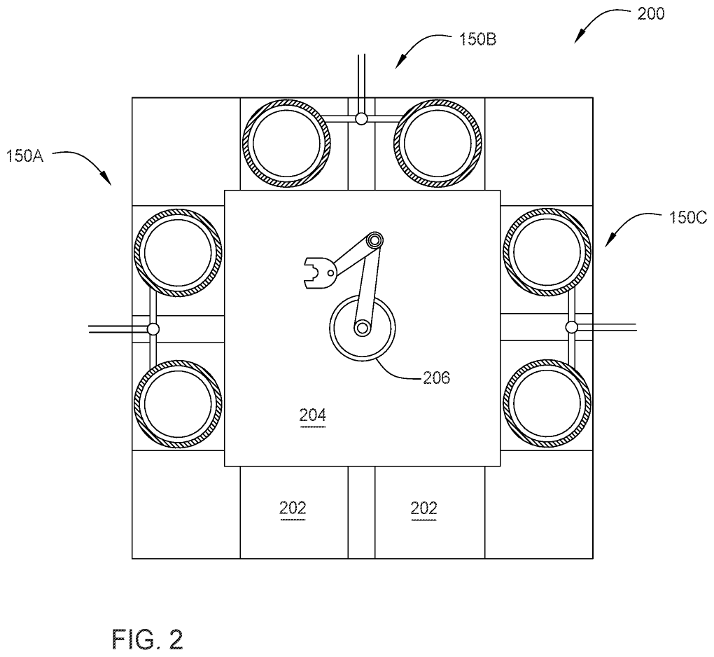

FIG. 2 is a schematic plan view of a multi-chamber processing system which may be used to perform the methods set forth herein, in accordance with an embodiment of the present disclosure.

FIG. 2 is a top down sectional view schematically illustrating a multi-chamber processing system 200, according to one embodiment, which may be used to perform the methods set forth herein. Here, the multi-chamber processing system 200 includes one or more load lock chambers 202 for receiving substrates into the processing system 200, a transfer chamber 204, and a plurality of processing systems 150A-C, here a first processing system 150A, a second processing system 150B, and an optional third processing system 150C. Each of the processing systems 150A-C are fluidly coupled to one another by the transfer chamber 204 disposed there between. The first processing system 150A is configured to perform the hydrogen radical treatment methods described herein and may be the same or substantially similar to the processing system 150 described in FIG. 1B. The second processing system 150B can include one or more deposition chambers, e.g., any one of a chemical vapor deposition (CVD) chamber, an atomic layer deposition (ALD) chamber, or a physical vapor deposition (PVD) chamber. In one embodiment, the optional third processing system 150C is an etch system. The transfer chamber 204 includes a substrate handler 206 to facilitate transfer substrates between the processing systems 150A-C. Here, the transfer chamber 202 is maintained under vacuum so that the substrate may be transferred between the processing chambers 150A-C to perform various aspects of the methods set forth herein without exposing the substrate to atmospheric conditions.

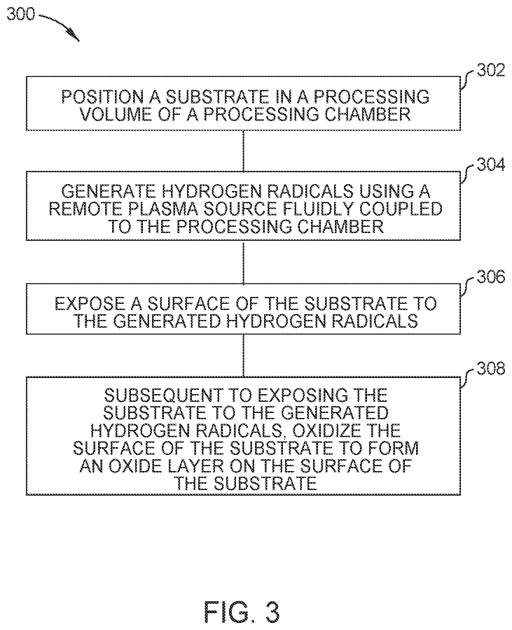

FIG. 3 is a diagram illustrating a method involving enhanced oxidation with hydrogen radical pretreatment, in accordance with an embodiment of the present disclosure.

Generally, an enhanced oxidation process may be plasma enhanced, where the method includes forming a plasma of one or both of the precursors to form radical species thereof and exposing the substrate to the plasma and/or the radical species formed therefrom. The plasma may be in-situ (formed in the processing volume), or may be formed remotely from the substrate, e.g., by use of a remote plasma source. In other embodiments, an enhanced oxidation process are thermal processes, e.g., where the substrate is heated to promote reactions at the surface thereof.

At operation 302, a method 300 of oxidizing a substrate includes positioning a substrate in a processing volume of a processing chamber.

In an embodiment, the substrate is or includes silicon, and an ultimately formed oxide layer is or includes silicon oxide.

At operation 304, the method 300 includes generating hydrogen radicals using a remote plasma source fluidly coupled to the processing chamber.

In a particular embodiment, the hydrogen radicals are formed by flowing hydrogen gas (H₂) into a remote plasma source (RPS) fluidly coupled to the processing volume and igniting and maintaining a plasma of the hydrogen gas to form radical species thereof. The hydrogen radicals are then flowed into the processing volume. Typically, the flowrate of hydrogen gas (H₂) to the RPS for processing of a 300 mm diameter substrate is between about 10 sccm and about 5000 sccm, such as between about 100 sccm and about 1500 sccm. Appropriate scaling may be used for different sized substrates. In other embodiments, a remote plasma may be formed in a portion of a processing volume of a processing chamber that is separated from the portion of the processing volume having the substrate disposed therein. For example, in such embodiments the remote plasma may be formed in a portion of a processing volume that is separated from the substrate processing portion by a showerhead.

Typically, the effluent from the RPS is flowed through an ion filter to remove substantially all ions therefrom before the hydrogen radicals reach the processing volume and the surface of the substrate disposed therein. In embodiments where the remote plasma is formed in a separate portion of the processing volume, a showerhead can be disposed between the remote plasma, and the substrate processing portion may be used as the ion filter.

At operation 306, the method 300 includes exposing a surface of the substrate to the generated hydrogen radicals.

In an embodiment, exposing the surface of the substrate to the generated hydrogen radicals is performed for a duration in the range of 1 second to 5 minutes. In an embodiment, exposing the surface of the substrate to the generated hydrogen radicals is performed at a temperature in the range of 25 degrees Celsius to 700 degrees Celsius. In an embodiment, exposing the surface of the substrate to the generated hydrogen radicals is performed using a gas flow of hydrogen (H₂) in a range of 1% to 100% total H₂ in the gas flow. In an embodiment, exposing the surface of the substrate to the generated hydrogen radicals is performed at a pressure in a range of 0.01 Torr to 20 Torr.

At operation 308, the method 300 includes, subsequent to exposing the substrate to the generated hydrogen radicals, oxidizing the surface of the substrate to form an oxide layer on the surface of the substrate.

In an embodiment, oxidizing the surface of the substrate is performed for a duration in the range of 1 second to 20 minutes. In an embodiment, oxidizing the surface of the substrate is performed at a temperature in the range of 25 degrees Celsius to 1200 degrees Celsius. In an embodiment, oxidizing the surface of the substrate is performed using a gas flow of water vapor (H₂O) or oxygen (O₂), or other oxidation source, in a range of 1% to 100% total oxidation source in the flow. In an embodiment, oxidizing the surface of the substrate is performed at a pressure in a range of 0.1 Torr to 800 Torr.

In an embodiment, subsequent to operation 308, the method 300 optionally includes a thermal bake process. The thermal bake process can include maintaining the substrate at the treatment temperature or heating the substrate to a second temperature that is different than the treatment temperature, and may be performed while concurrently flowing hydrogen gas into the processing volume. Typically, flowing hydrogen gas into the processing volume includes extinguishing the plasma formed in the RPS while continuing to flow hydrogen gas there into. The hydrogen gas may be flowed at the about the same flowrate as during the hydrogen radical treatment of operation 306 or may be increased or decreased relative thereto. A bake may be performed in the same processing chamber as operations 302, 304, 306 and 308. In other embodiments, the substrate may be transferred under vacuum to a second processing chamber of a multi-chamber processing system and the thermal bake process may be performed in the second processing chamber.

In an embodiment, a semiconductor wafer or substrate for thermal oxidation is composed of a material suitable to withstand a fabrication process and upon which semiconductor processing layers may suitably be disposed. For example, in one embodiment, a semiconductor wafer or substrate is composed of a group IV-based material such as, but not limited to, crystalline silicon, germanium or silicon/germanium. In a specific embodiment, the semiconductor wafer includes is a monocrystalline silicon substrate. In a particular embodiment, the monocrystalline silicon substrate is doped with impurity atoms. In another embodiment, the semiconductor wafer or substrate is composed of a III-V material.

Embodiments of the present disclosure may be provided as a computer program product, or software, that may include a machine-readable medium having stored thereon instructions, which may be used to program a computer system (or other electronic devices) to perform a process according to embodiments of the present disclosure. In one embodiment, the computer system is coupled with a process chamber or system such as described above in association with FIGS. 1A, 1B and 2. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

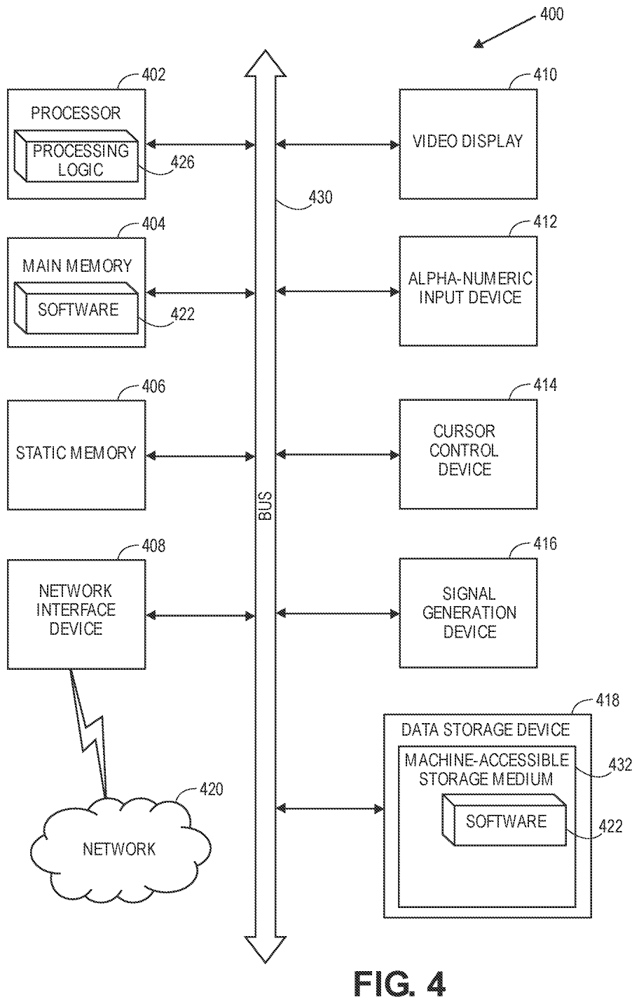

FIG. 4 illustrates a diagrammatic representation of a machine in the exemplary form of a computer system 400 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 400 includes a processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a secondary memory 418 (e.g., a data storage device), which communicate with each other via a bus 430.

Processor 402 represents one or more general-purpose processing devices such as a microprocessor, central processing unit, or the like. More particularly, the processor 402 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 402 may also be one or more special-purpose processing devices such as an application specific integrated circuit (ASIC), a field programmable gate array (FPGA), a digital signal processor (DSP), network processor, or the like. Processor 402 is configured to execute the processing logic 426 for performing the operations described herein.

The computer system 400 may further include a network interface device 408. The computer system 400 also may include a video display unit 410 (e.g., a liquid crystal display (LCD), a light emitting diode display (LED), or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium (or more specifically a computer-readable storage medium) 432 on which is stored one or more sets of instructions (e.g., software 422) embodying any one or more of the methodologies or functions described herein. The software 422 may also reside, completely or at least partially, within the main memory 404 and/or within the processor 402 during execution thereof by the computer system 400, the main memory 404 and the processor 402 also constituting machine-readable storage media. The software 422 may further be transmitted or received over a network 420 via the network interface device 408.

While the machine-accessible storage medium 432 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

Thus, enhanced oxidation with hydrogen radical pretreatment has been disclosed.

What is claimed is:

1. A method of oxidizing a substrate, the method comprising:
positioning a substrate in a processing volume of a processing chamber;
generating hydrogen radicals using a remote plasma source fluidly coupled to the processing chamber;
exposing a surface of the substrate to the generated hydrogen radicals; and
subsequent to exposing the substrate to the generated hydrogen radicals, oxidizing the surface of the substrate to form an oxide layer on the surface of the substrate.

2. The method of claim 1, wherein the substrate comprises silicon, and the oxide layer comprises silicon oxide.

3. The method of claim 1, wherein exposing the surface of the substrate to the generated hydrogen radicals is performed for a duration in the range of 1 second to 5 minutes.

4. The method of claim 1, wherein exposing the surface of the substrate to the generated hydrogen radicals is performed at a temperature in the range of 25 degrees Celsius to 700 degrees Celsius.

5. The method of claim 1, wherein exposing the surface of the substrate to the generated hydrogen radicals is performed using a gas flow of hydrogen (H₂) in a range of 1% to 100% total H₂ in the gas flow.

6. The method of claim 1, wherein exposing the surface of the substrate to the generated hydrogen radicals is performed at a pressure in a range of 0.01 Torr to 20 Torr.

7. The method of claim 1, wherein oxidizing the surface of the substrate is performed for a duration in the range of 1 second to 20 minutes.

8. The method of claim 1, wherein oxidizing the surface of the substrate is performed at a temperature in the range of 25 degrees Celsius to 1200 degrees Celsius.

9. The method of claim 1, wherein oxidizing the surface of the substrate is performed using a gas flow of water vapor (H₂O) or oxygen (O₂), or other oxidation source, in a range of 1% to 100% total oxidation source in the flow.

10. The method of claim 1, wherein oxidizing the surface of the substrate is performed at a pressure in a range of 0.1 Torr to 800 Torr.

11. A processing chamber for performing a method of oxidizing a substrate, the method comprising:
positioning a substrate in a processing volume of a processing chamber;
generating hydrogen radicals using a remote plasma source fluidly coupled to the processing chamber;
exposing a surface of the substrate to the generated hydrogen radicals; and
subsequent to exposing the substrate to the generated hydrogen radicals, oxidizing the surface of the substrate to form an oxide layer on the surface of the substrate.

12. The processing chamber of claim 11, wherein the substrate comprises silicon, and the oxide layer comprises silicon oxide.

13. The processing chamber of claim 11, wherein exposing the surface of the substrate to the generated hydrogen radicals is performed for a duration in the range of 1 second to 5 minutes.

14. The processing chamber of claim 11, wherein exposing the surface of the substrate to the generated hydrogen radicals is performed at a temperature in the range of 25 degrees Celsius to 700 degrees Celsius.

15. The processing chamber of claim 11, wherein exposing the surface of the substrate to the generated hydrogen radicals is performed using a gas flow of hydrogen (H₂) in a range of 1% to 100% total H₂ in the gas flow.

16. The processing chamber of claim 11, wherein exposing the surface of the substrate to the generated hydrogen radicals is performed at a pressure in a range of 0.01 Torr to 20 Torr.

17. The processing chamber of claim 11, wherein oxidizing the surface of the substrate is performed for a duration in the range of 1 second to 20 minutes.

18. The processing chamber of claim 11, wherein oxidizing the surface of the substrate is performed at a temperature in the range of 25 degrees Celsius to 1200 degrees Celsius.

19. The processing chamber of claim 11, wherein oxidizing the surface of the substrate is performed using a gas flow of water vapor (H₂O) or oxygen (O₂), or other oxidation source, in a range of 1% to 100% total oxidation source in the flow.

20. The processing chamber of claim 11, wherein oxidizing the surface of the substrate is performed at a pressure in a range of 0.1 Torr to 800 Torr.
